(19) United States
(12) Patent Application Publication
(10) Pub. No.: US 2013/0027106 A1
(43) Pub. Date: Jan. 31, 2013

(54) POWER CONTROL CIRCUIT

(71) Applicants: YING-BIN FU, Shenzhen City (CN); LAN-YI FENG, Shenzhen City (CN)

(72) Inventors: YING-BIN FU, Shenzhen City (CN); LAN-YI FENG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/302,933

(22) Filed: Nov. 22, 2011

(30) Foreign Application Priority Data
Jul. 27, 2011 (CN) 201110212123.8

(51) Int. Cl. H03L 5/00

(52) U.S. Cl. 327/306

(57) ABSTRACT

A power control circuit includes a voltage output terminal, a control chip, a converter, and a comparator. A voltage input pin of the control chip is connected to a first power source. A voltage pin of the converter is connected to a second power source. A pulse input pin of the converter is connected to a pulse output pin of the control chip. An output pin of the converter is connected to the voltage output terminal. An inverting input terminal of a comparator is connected to a voltage output pin of the control chip. A non-inverting input terminal of the comparator is connected to the second power source through a first resistor and grounded through a second resistor. An output terminal of the comparator is connected to a detecting pin of the control chip and connected to the non-inverting input terminal of the comparator through a third resistor.

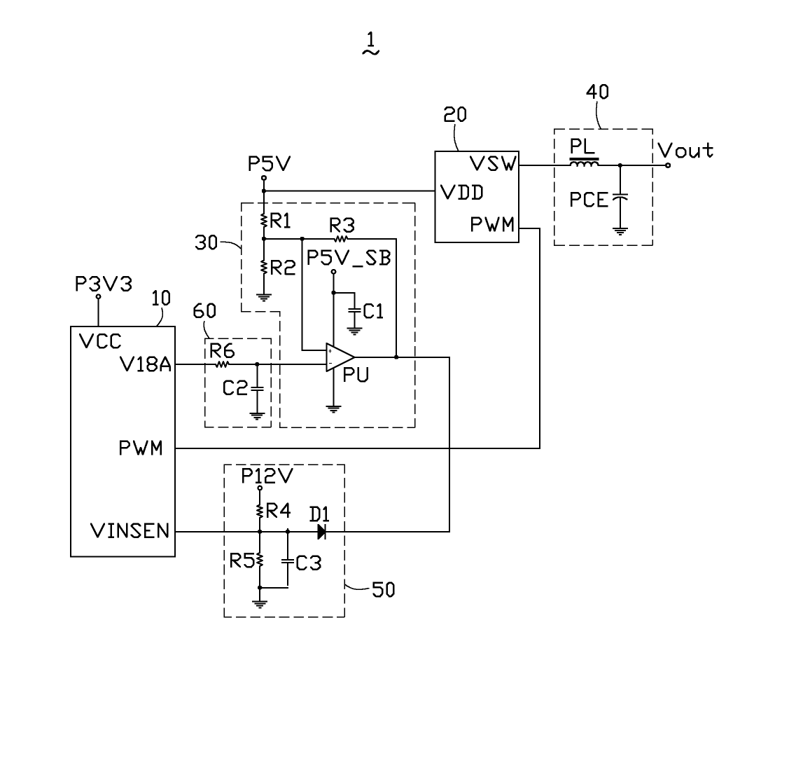

### BACKGROUND

1. Technical Field

The present disclosure relates to a power control circuit.

2. Description of Related Art

In a computer, a control chip outputs a pulse width modulation (PWM) signal to drive a converter. However, the converter functions in response to receiving the PWM signal after the converter receives a working voltage, otherwise, the converter will be damaged in response to receiving the PWM signal before receiving the working voltage. Therefore, there is room for improvement in the art.

### BRIEF DESCRIPTION OF THE DRAWING

Many aspects of the embodiments can be better understood with reference to the following drawing. The components in the drawing are not necessarily drawn to scale, the emphasis instead being placed upon clearly illustrating the principles of the present embodiments.

The FIGURE is a circuit diagram of a power control circuit in accordance with an exemplary embodiment of the present disclosure.

### DETAILED DESCRIPTION

The disclosure, including the drawing, is illustrated by way of example and not by way of limitation. References to “an” or “one” embodiment in this disclosure are not necessarily to the same embodiment, and such references mean at least one.

Referring to the FIGURE, a power control circuit 1 in accordance with an exemplary embodiment includes a control chip 10, a converter 20, a comparing circuit 30, a first filtering circuit 40, a feedback circuit 50, a second filtering circuit 60, and a voltage output terminal Vout. The comparing circuit 30 compares a working voltage of the converter 20 with a reference voltage outputted from the control chip 10 and filtered through the second filtering circuit 60, and outputs a comparing signal to the feedback circuit 50. The feedback circuit 50 receives the comparing signal and outputs a feedback signal to the control chip 10. The control chip 10 receives the feedback signal and outputs a driving signal to the converter 20. The converter 20 converts the working voltage and outputs the converted voltage to a peripheral device (not shown) through the voltage output terminal Vout after receiving the driving signal. In one embodiment, a type of the control chip 10 may be CHL832X.

The control chip 10 includes a voltage input pin VCC, a voltage output pin V18A, a pulse output pin PWM, and a detecting pin VINsen. The voltage input pin VCC is connected to a power source P3V3. The voltage output pin V18A is connected to the second filtering circuit 60. The pulse output pin PWM is connected to the converter 20. The detecting pin VINsen is connected to the feedback circuit 50. When the detecting pin VINsen receives a low level signal (e.g. logic 0) from the feedback circuit 50, the pulse output pin PWM does not output a driving signal to the converter 20. When the detecting pin VINsen receives a high level signal (e.g. logic 1) from the feedback circuit 50, the pulse output pin PWM outputs a driving signal to the converter 20, to drive the converter 20 to convert the working voltage.

The converter 20 includes a voltage pin VDD to receive the working voltage P5V, an output pin VSW, and a pulse input pin PWM. The voltage pin VDD is connected to a power source P5V. The pulse input pin PWM is connected to the pulse output pin PWM of the control chip 10. The output pin VSW is connected to the first filtering circuit 40.

The first filtering circuit 40 includes an inductor PL and a capacitor PCE. A first end of the inductor PL is connected to the output pin VSW of the converter 20, and a second end of the inductor PL is connected to the voltage output terminal Vout and also grounded through the capacitor PCE.

The second filtering circuit 60 includes a resistor R6 and a capacitor C2. A first end of the resistor R6 is connected to the voltage output pin V18A of the control chip 10, and a second end of the resistor R6 is connected to the comparing circuit 30 and also grounded through the capacitor C2.

The comparing circuit 30 includes a comparator PU, resistors R1-R3, and a capacitor C1. An inverting input terminal of the comparator PU is connected to the second end of the resistor R6. A non-inverting input terminal of the comparator PU is connected to the power source P5V through the resistor R1 and also grounded through the resistor R2. An output terminal of the comparator PU is connected to the non-inverting input terminal of the comparator PU through the resistor R3 and also connected to the feedback circuit 50. A voltage terminal of the comparator PU is connected to a power source P5V_SB and also connected to a first end of the capacitor C1. A second end of the capacitor C1 is grounded. A ground terminal of the comparator PU is grounded.

The feedback circuit 50 includes resistors R4 and R5, a diode D1, and a capacitor C3. An anode of the diode D1 is connected to the detecting pin VINsen of the control chip 10 and also connected to a power source P12V through the resistor R4. The resistor R5 and the capacitor C3 are connected in parallel between the anode of the diode D1 and ground. A cathode of the diode D1 is connected to the output terminal of the comparator PU.

In use, when the power control circuit 1 receives power, the working voltage provided to the converter 20 is provided later than the voltage provided to the control chip 10. The voltage output pin V18A of the control chip 10 outputs a reference voltage to the inverting input terminal of the comparator PU through the second filtering circuit 60. The non-inverting input terminal of the comparator PU does not receive a voltage. The output terminal of the comparator PU outputs a low level signal to the cathode of the diode D1. The diode D1 is turned on. The control chip 10 receives the low level signal through the detecting pin VINsen and controls the pulse output pin PWM not to output a driving signal to the pulse input pin of the converter 20. Thus, the converter 20 does not receive a driving signal before the converter 20 receives a working voltage, thus avoiding the possibility of damage.

When the converter 20 receives a working voltage, the voltage of the non-inverting input terminal of the comparator PU is greater than the reference voltage of the inverting input terminal of the comparator PU. The output terminal of the comparator PU outputs a high level signal to the cathode of the diode D1. The diode D1 is turned off. The control chip 10 receives a high level signal through the detecting pin VINsen and controls the pulse output pin PWM to output a driving signal to the pulse input pin PWM of the converter 20. The converter 20 converts the working voltage and outputs the converted voltage to the peripheral device through the first filtering circuit 40 and the voltage output terminal Vout, in that order.

When the power control circuit 1 is powered off, the converter 20 loses power before the control chip 10 loses power. The voltage output pin V18A of the control chip 10 continues to output the reference voltage to the inverting input terminal of the comparator PU. The non-inverting input terminal of the comparator PU does not receive a voltage. The output terminal of the comparator PU outputs a low level signal to the cathode of the diode D1. The diode D1 is turned on. The control chip 10 receives a low level signal through the detecting pin VINsen and controls the pulse output pin PWM not to output a driving signal to the pulse input pin PWM of the converter 20. Thus, the converter 20 will not receive any driving signal after the converter 20 has stopped receiving a working voltage, again avoiding the possibility of damage.

The control chip 10 controls the driving signal outputted from the pulse output pin PWM to the converter 20 according to a feedback signal received by the feedback pin VINsen, to control the converter 20 to avoid any damage.

Even though numerous characteristics and advantages of the disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A power control circuit, comprising:
a voltage output terminal;
a control chip comprising a voltage input pin connected to a first power source, a voltage output pin, a pulse output pin, and a detecting pin;
a converter comprising a voltage pin connected to a second power source, an output pin connected to the voltage output terminal, and a pulse input pin connected to the pulse output pin of the control chip; and
a comparing circuit comprising first to third resistors and a comparator, wherein an inverting input terminal of the comparator is connected to the voltage output pin of the control chip, a non-inverting input terminal of the comparator is connected to the second power source through the first resistor and also grounded through the second resistor, the output terminal of the comparator is connected to the detecting pin of the control chip and also connected to the non-inverting input terminal of the comparator through the third resistor, a voltage terminal of the comparator is connected to a third power source.

2. The power control circuit of claim 1, wherein the comparing circuit further comprises a first capacitor connected between the third power source and ground.

3. The power control circuit of claim 2, further comprising a feedback circuit, wherein the feedback circuit comprises fourth and fifth resistors, and a diode, an anode of the diode is connected to the detecting pin of the control chip and also connected to a fourth power source through the fourth resistor, the fifth resistor is connected between the anode of the diode and ground, a cathode of the diode is connected to the output terminal of the comparator.

4. The power control circuit of claim 3, wherein the feedback circuit further comprises a second capacitor, the second capacitor is connected between the anode of the diode and ground.

5. The power control circuit of claim 4, further comprising a first filtering circuit, wherein the first filtering circuit comprises an inductor and a third capacitor, a first end of the inductor is connected to the output pin of the converter, and a second end of the inductor is connected to the voltage output terminal and also grounded through the third capacitor.

6. The power control circuit of claim 5, further comprising a second filtering circuit, wherein the second filtering circuit comprises a sixth resistor and a fourth capacitor, a first end of the sixth resistor is connected to the voltage output pin of the control chip, and a second end of the sixth resistor is connected to the inverting input terminal of the comparator and also grounded through the fourth capacitor.
